(19) United States
(12) Patent Application Publication
(10) Pub. No.: US 2016/0042943 A1
(43) Pub. Date: Feb. 11, 2016

(54) LOW-K DIELECTRIC FILM FORMATION

(71) Applicant: Lam Research Corporation, Fremont, CA (US)

(72) Inventors: Troy Daniel Ribaudo, Portland, OR (US); George Andrew Antonelli, Portland, OR (US)

(21) Appl. No.: 14/479,130

(22) Filed: Sep. 5, 2014

Related U.S. Application Data
(60) Provisional application No. 62/034,552, filed on Aug. 7, 2014.

(51) Int. Cl. H01L 21/02; H01J 37/32; H01L 21/67

(52) U.S. Cl. CPC H01L 21/02203; H01L 21/0234; H01L 21/02348; H01L 21/67069; H01J 37/321; H01J 37/32899; H01J 37/32926; H01J 2237/334

(57) ABSTRACT

Methods and apparatus for fabricating a porous, low-k dielectric film are described. In some implementations, the methods include exposing a precursor film including a porogen within a matrix to a plasma generated from a weak oxidizer. The plasma may also include reducing agent species. In some implementations, the plasma is a downstream plasma. Implementations of the method involve selectively removing regions of isolated, organic porogen co-existing within a silicon-organic matrix by exposure to the plasma while preserving the organic groups bonded to the backbone of the silicon matrix. The methods also result in low damage to the dielectric film. In some implementations, plasma exposure is followed by exposure to ultraviolet (UV) radiation.

### CROSS-REFERENCE TO RELATED APPLICATION

This application claims priority to U.S. Provisional Patent Application No. 62/034,552 filed Aug. 7, 2014, titled LOW-K DIELECTRIC FILM FORMATION. This provisional patent application is incorporated herein by reference in its entirety for all purposes.

### BACKGROUND

As integrated circuits (IC) feature sizes shrink, problems of increased resistance and resistance-capacitance (RC) coupling offset any speed advantage derived from the smaller device size, limiting improvement in device performance. Ways to improve device performance and reliability include using highly conductive metals, such as copper, and employing lower dielectric constant (low-k) materials.

Low-k materials are semiconductor-grade insulating materials that have a dielectric constant (k) lower than that of silicon dioxide SiO₂, i.e., 3.9. With more and more advanced technology needs, ultra low-k dielectric (ULK) materials having a k less than 2.5 are used. ULK dielectrics can be obtained by incorporating voids within a low-k dielectric, creating a porous dielectric material. Applications of ULK dielectrics include back end of line (BEOL) interlayer dielectrics (ILDs).

### SUMMARY

One aspect of the methods disclosed herein relates to a method of forming a porous dielectric film. The method involves providing a precursor film including a dielectric matrix and a porogen and exposing the precursor film to a downstream plasma generated from a process gas including a reducing agent and a weak oxidizer to thereby remove porogen and form a porous dielectric film. In some embodiments, the porous dielectric film may be exposed to UV radiation to increase cross-linking Such exposure may involve exposure to one or multiple emission spectra. For example, in some embodiments, the porous dielectric film is exposed to a first emission spectrum and then exposed film to a second emission spectrum, wherein the first and second emission spectra are different.

Examples of weak oxidizers include carbon dioxide, water, methanol, ethanol, isopropyl alcohol, and combinations thereof. Examples of reducing agents include molecular hydrogen, ammonia, acetic acid, formic acid, and combinations thereof. In some embodiments, the reducing agent is molecular hydrogen and the weak oxidizer is carbon dioxide. In some embodiments, a weak oxidizer:reducing agent volumetric flow ratio is 1:1 or greater. In some embodiments, a weak oxidizer:reducing agent volumetric flow ratio is between 1:1 and 2:1.

The plasma may be generated by an inductively-coupled plasma generator in some embodiments. Radical species may be predominant in the downstream plasma. In some embodiments, a power used to generate the downstream plasma is between about 1.0 and 1.8 Watts per cm2 of surface area of a substrate on which the precursor film is disposed.

Another aspect of the disclosure is an apparatus for forming a porous dielectric film. The apparatus may include a processing chamber; a substrate support for holding a substrate in the processing chamber; a remote plasma source over the substrate support; a showerhead between the remote plasma source and the substrate support; and a controller with instructions to perform the following operations: (a) receiving a substrate including a precursor film including a dielectric matrix and a porogen; (b) inletting reducing agent and a weak oxidizer gases into the remote plasma source; (c) applying a power to the remote plasma generator to generate plasma species from the reducing agent and a weak oxidizer gases; (d) directing remote plasma species including weak oxidizer and reducing agent species through the showerhead; and (e) exposing a substrate to the remote plasma species in (c).

In some embodiments, the controller includes instructions to inlet the reducing agent and a weak oxidizer gases into the remote plasma generator at a weak oxidizer:reducing agent volumetric flow ratio between 1:1 and 2:1. In some embodiments the controller includes instructions to apply a power between 1 and 1.8 Watts per cm2 of surface area of the substrate. The apparatus may further include a UV cure chamber. In some embodiments, the controller includes instructions to, after (e), expose the substrate to UV radiation. The controller may include instructions to expose the porous dielectric film to a first emission spectrum and then expose the porous dielectric film to a second emission spectrum, wherein the first and second emission spectra are different.

These and other aspects are described below with reference to the Drawings.

### BRIEF DESCRIPTION OF THE DRAWINGS

FIG. 1 is a process flow chart depicting an example of a method of removing porogen from a dielectric precursor film.

FIG. 2 is a process flow chart depicting examples of methods of forming a low-k dielectric film.

FIG. 3 shows single variable plots of porogen removal and damage using a CO₂/H₂ plasma treatment as functions of the following variables: process pressure, RF power, CO₂:total gas flow ratio, and pedestal temperature.

FIG. 4 shows SiCH₃ cross-linking versus Bulb B cure time and versus Bulb AB cure time.

FIG. 5a shows an example of a cross-sectional schematic diagram of a plasma apparatus with a processing chamber.

FIG. 5b shows an example of a cross-sectional schematic diagram of a UV apparatus with a processing chamber.

FIG. 6 shows an example of a block diagram of an arrangement of a plasma apparatus and a UV cure apparatus.

### DETAILED DESCRIPTION

In the following description, numerous specific details are set forth in order to provide a thorough understanding of the present disclosure, which pertains to porogen removal during formation of a porous dielectric material on a substrate. Implementations of the present disclosure may be practiced without some or all of these specific details. In other instances, well known process operations have not been described in detail to not unnecessarily obscure the description. While the subject matter of the disclosure is described in conjunction with the specific embodiments, it will be understood that it is not intended to limit the scope of the disclosure to these embodiments.

For many embodiments, the substrate is a semiconductor wafer. A semiconductor wafer as discussed in this document is a semiconductor substrate at any of the various states of manufacture/fabrication in the production of integrated circuits. It is noted that the methods and apparatus disclosed herein are not limited to semiconductor wafers. For example, these methods and apparatus may be used for fabrication or treatment of mesoporous molecular sieves.

Methods described herein involve forming a low-k dielectric material by way of a dielectric precursor layer that contains both a porogen and a dielectric matrix formed in regions around the porogen. The porogen is removed from the precursor layer to create a low-k dielectric layer. Within the precursor layer, the porogen resides in locations that will subsequently become void locations in the final dielectric layer. Hence, the porogen and dielectric matrix typically exist as separate phases within the precursor layer. To some degree, the porogen defines the porosity, void volume, tortuosity and other parameters characterizing the pore morphology in the final low-k dielectric material. In some cases, the pore morphology is set before the porogen is removed. In other cases, it is set during the porogen removal process. Further, the dielectric matrix may assume its final composition and structure either before or during the porogen removal process. In alternative methods, the structure former and porogen are deposited separately in a two-phase process. For example, in some mesoporous films, a template-forming precursor, solvent and catalyst are mixed and applied by spin-coat or print-on methods to form a template in a first process phase, then a silica-forming precursor is introduced to the formed template in a second process step such as supercritical infusion into a polymer matrix. Depending on the application, the thickness of the precursor film may range between about 10 nanometers and 3 micrometers in some examples.

Generally, a porogen is any removable material that defines void regions in a dielectric matrix. This does not include small organic end groups on a structure former backbone that can be, though often are preferably not, removed from the precursor film.

In the case of an ordered porous or mesoporous dielectric matrix, the porogen is frequently referred to as a “template.” In many cases, the porogen is or includes an organic material.

In some cases the porogen is randomly distributed throughout the precursor film and other cases it is ordered in a repeating structure throughout the film. One type of ordered porogen, for example, is a block copolymer that has chemically distinct components (e.g., polyethylene oxide (PEO) and polypropylene oxide (PPO)) that segregate into separate phases. The discussion herein will refer to porogen and porogen materials in general and are intended to include any type of porogen, ordered or non-ordered, organic or inorganic, unless otherwise specified.

Frequently, the porogen is a hydrocarbon. The following is a non-comprehensive list of precursor films (listed by type of porogen molecules) that may be suitable. “Low temperature porogens” are deposited below about 200° C. and “high temperature porogens” are deposited above about 200° C.

One class of porogens is polyfunctional cyclic non-aromatic compounds, such as alpha-terpinenes (ATRPs). Suitable alpha-terpinene derivatives include, for example, alpha-terpinene itself, substituted alpha-terpinenes, and multi-ring compounds containing the alpha-terpinene nucleus. Other compounds include functional groups such as —CH═CH₂, —CH═CH—, —C≡CH, —C≡C—, —C═O, —OCH₃. An n example of one of these compounds is 1,2,3,4-tetramethyl-1,3-cyclopentadiene (TMCP) (C₉H₁₄). Three-dimensional multi-ring compounds such as 5-ethylidene-2-norbornene (ENB) are also suitable. Another ATRP compound that can be used is D-limonene.

In some cases, the porogen and structure former reside in the same compound. That is, the porogen is a removable moiety in a compound that contains moieties serving as structure formers covalently bonded to moieties serving as the porogen. Nominally, the porogen moiety is a large bulky organic substituent that will leave pores in the resulting dielectric film. Examples of such species are organic silanes such as di-tert-butylsilane, phenyldimethylsilane, and alkoxysilanes such as 5-(bicycloheptenyl)methyldimethoxysilane (BMDS) and 5-(bicycloheptenyl)triethoxysilane (BTS) (SiCl₃O₃H₂₄). These compounds may be deposited using CVD or spin on methods, for example.

As indicated, the structure former serves as a backbone for the resulting porous low-k film. Many different chemical compositions may be used as the structure former. In some embodiments, the composition includes silicon and oxygen. Sometimes it also includes carbon and/or other elements and even metals. For relatively thick precursor layers, it will sometimes be desirable to use structure formers that are not opaque to the UV radiation.

Examples of precursors for structure formers include silanes, alkylsilanes (e.g., trimethylsilane and tetramethylsilane), alkoxysilanes (e.g., methyltriethoxysilane (MTEOS), methyltrimethoxysilane (MTMOS) diethoxymethylsilane (DEMS), methyldimethoxysilane (MDMOS), methyldiethoxy silane (MDEOS), trimethylmethoxysilane (TMMOS) and dimethyldimethoxysilane (DMDMOS)), linear siloxanes and cyclic siloxanes (e.g. diethylmethylsiloxane (DEMS), octamethylcyclotetrasiloxane (OMCTS), tetramethylcyclotetrasiloxane (TMCTS)). Note that one example of a silane is di-tert-butylsilane, described above.

The thickness of the precursor film (and hence the resulting dielectric layer) depends upon the ultimate application. For an interlayer dielectric or packaging application, the thickness may range from 100 angstroms up to about 2 to 3 microns. In some cases, extra thickness provides some amount of sacrificial dielectric to accommodate a subsequent planarization step. Thinner precursor films may be increasingly used with increasingly smaller technology nodes. For example, many of the processes described herein may be advantageously used with thin films of less than 200 nm.

The porosity of the dielectric film may be connected, and may include pores that are introduced by removal of a porogen from a dielectric matrix and/or pores that are inherent to the dielectric matrix. For example, a CDO matrix may have porosity due the incorporation of methyl or other organic groups that remain in the CDO matrix after porogen removal. The porous dielectric film may include mesoporosity and/or microporosity. Mesoporosity generally refers to pore sizes of 2 nm-50 nm and microporosity to pore sizes less than 2 nm. In dielectrics having connected porosity, the size of at least some of the connected pores may be on a continuum with micropores having sizes on the order of angstroms to nanometers, connected to mesopores having sizes on the order of nanometers to tens of nanometers.

As noted above, a precursor may include both a porogen and organic groups directly bonded to organic-silicon oxide matrix. In many cases, removal of former is desirable while removal of the latter is not. This is because non-porogen organic end groups are introduced to increase porosity. In some implementations, for example, microporosity may be incorporated into an ultra low-k (ULK) dielectric by organic end groups in a silicon oxide matrix and mesoporosity may be incorporated into a ULK dielectric by removal of a porogen.

Methods of porogen removal suffer from various drawbacks. Plasma treatments have a very limited penetration depth for dense films (e.g., films having unconnected porosity) making through film curing untenable for certain films of thickness greater than 50 nm depending on the density of the film in question. Also, these treatments lead to little or no matrix cross-linking Plasma detemplating of porogen performed on films having unconnected porosity results in a hard crust of material at the top of the film. Current cure technology for ULK thin films relies on the application of ultraviolet (UV) light and elevated temperature. The goal of this thermal UV process is to both remove the porogen to lower the effective dielectric constant of the thin film as well as cross-link the matrix of the ULK thin film to increase its mechanical properties. However, as the application of UV light both removes porogen and cross-links the silicon-organic matrix simultaneously, there is a limitation on the obtainable final properties of the cured film. Excessive cross-linking can lead not only to an increase in the dielectric constant but also to the trapping of porogen inside the ULK thin film leading to increased electrical leakage and degraded time-dependent-dielectric-breakdown (TDDB) at end of line integration.

Further, various methods including plasma exposure are susceptible to damaging the dielectric material by removing too many organic groups on the backbone of the silicon-organic matrix.

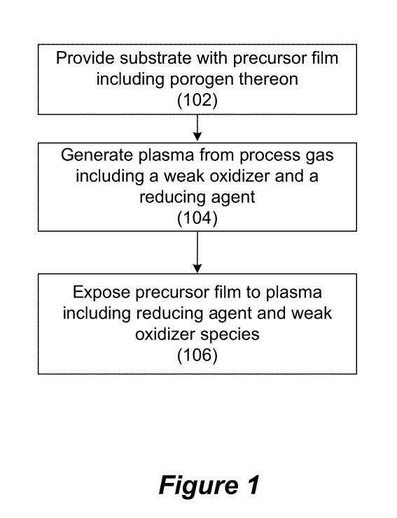

FIG. 1 is a process flow chart depicting an example of a method of removing porogen from a dielectric precursor film. The methods depicted in FIG. 1 may be used to selectively remove porogen without removing organic end groups that form part of the desired final dielectric film. First, in substrate having a precursor film is provided, typically in a processing chamber. (Block 102). Examples of precursor films and methods of depositing precursor films are given above. Providing a substrate to a processing chamber may involve transferring the substrate from another chamber. Alternatively, the substrate may remain in a processing chamber used to perform a previous operation such as deposition of the precursor film.

Next, a plasma is generated from a process gas that includes a weak oxidizer and a reducing agent. (Block 104). Examples of weak oxidizers include carbon dioxide (CO₂), water (H₂O), methanol (CH₃OH), ethanol (C₂H₅OH), isopropyl alcohol (C₃H₇OH), other oxygen-containing hydrocarbons (CₓH_{y}O_{z}), and combinations thereof. The process gas may be free of strong oxidizers, such as molecular oxygen (O₂), nitrogen oxides such as nitrous oxide (N₂O), sulfur oxides such as sulfur dioxide (SO₂), and stronger oxidizers. Plasmas that include multiple radical and ion species whose oxidation potential for removal of carbon from a low-k matrix (e.g., O₂ and N₂O plasmas) may be avoided. Examples of reducing agents include molecular hydrogen (H₂), ammonia (NH₃), acetic acid (C₂H₄O₂), and formic acid (HCO₂H). According to various embodiments, an inert carrier gas may or may not accompany the weak oxidizer and the reducing agent. For example, argon (Ar), helium (He), or nitrogen (N₂) may be up to 75% of the total volumetric flow, with the balance being the weak oxidizer and reducing agent. As such, in some embodiments, the process gas may consist essentially of one or more weak oxidizers, one or more reducing agents, and, optionally, an inert gas. Trace amounts of other compounds (e.g., from impurities) may be present.

The precursor film in then exposed to the plasma containing weak oxidizer and reducing agent species. (Block 106). As is discussed further below, this results in high porogen removal at low levels of damage to the dielectric material.

In some implementations, the plasma is generated in a plasma generator that is remote to the processing chamber. In such implementations, the plasma that is delivered to the processing chamber may be referred to as a downstream (rather than direct) plasma, and may contain significantly more radical species than ionic species. In some other implementations, the plasma may be a direct plasma.

A downstream plasma will behave very differently than a direct plasma. Using a downstream plasma can facilitate porogen removal without removing methyl or other groups that are chemically bonded to the backbone. Activated species including ions, radicals, and photons will be generated in the plasma generator. However, for treating low-k films, ion sputtering will tend to result in removal of these organic groups. Radical species, by contrast, can be selective as they interact chemically rather than physically with the film. While photochemical reactions can be selective, for ULK films high energy photons generated in a plasma may sever C—Si bonds, causing damage.

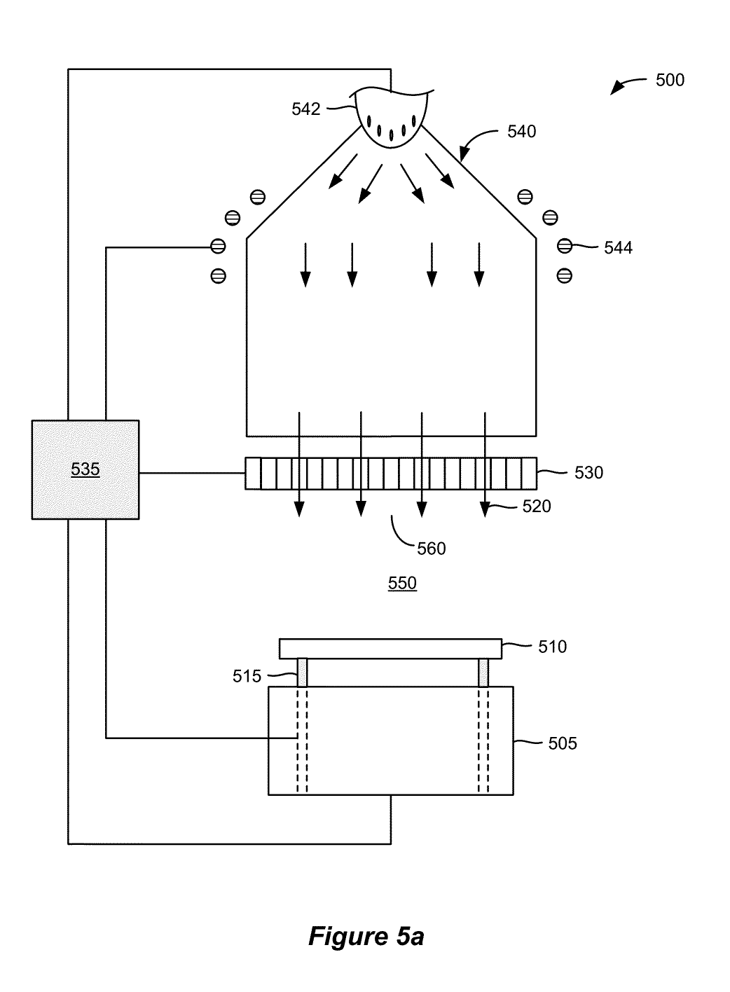

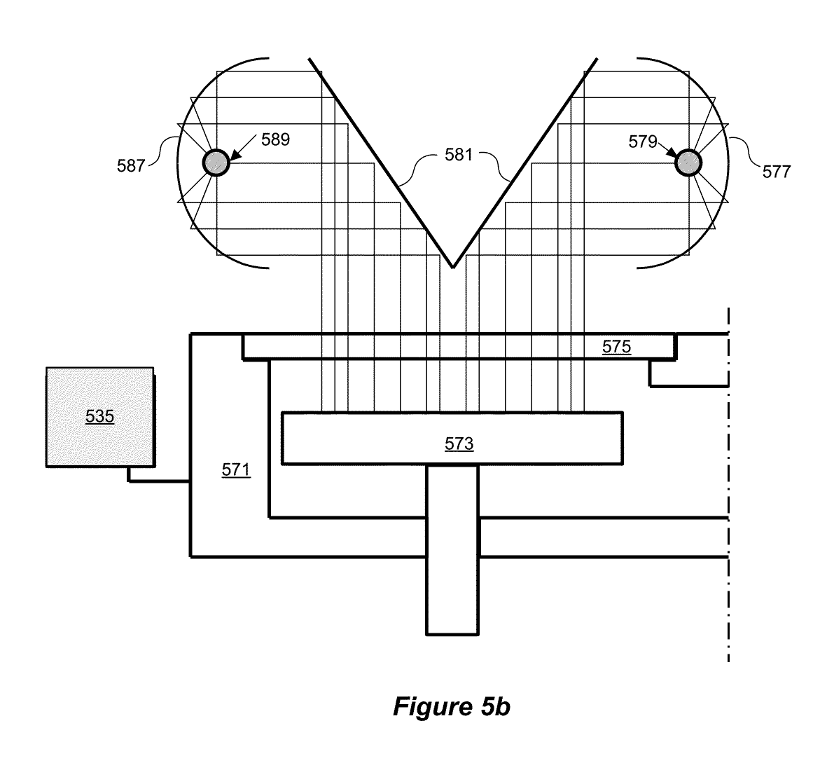

Accordingly, in some implementations, a downstream plasma having high energy ionic and/or photonic species filtered out is used. A showerhead interposed between the remote plasma generator and the processing chamber may serve to filter such species out. Examples of such apparatus are described below with reference to FIG. 5a. In some implementations, the porosity in the film as the porogen is removed is connected, allowing the plasma to penetrate the entire thickness of the film.

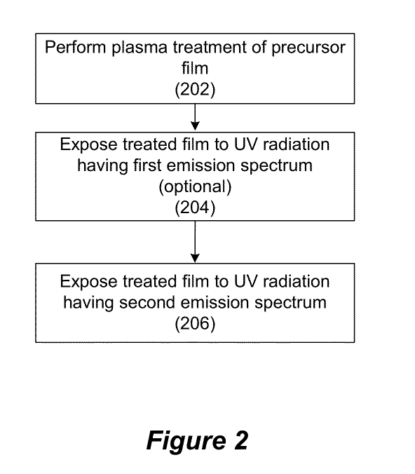

FIG. 2 is a process flow chart depicting examples of methods of forming a low-k dielectric film. The process of FIG. 2 begins by plasma treating a dielectric precursor film. (Block 202). In some implementations, block 202 involves a process as described above with respect to FIG. 1.

Generally, after block 202 is performed, a substantial amount of the porogen is removed. For example, at least 50% or even 90% of the porogen may be removed. Next, the treated film is optionally exposed to UV light having a first emission spectrum. (Block 204). In some implementations, the first emission spectrum is selected to preferentially remove organic porogen by driving a photolysis reaction in the porogen without significantly cross-linking the dielectric matrix. An example is a UV radiation source having only wavelengths greater than 250 nm. The treated film is then exposed to UV light having a second emission spectrum. (Block 206). In implementations in which block 204 is performed, the second emission spectrum in block 206 differs from the first emission spectrum. If block 204 is not performed, the second emission spectrum may be any appropriate emission spectrum. Block 206 may increase cross-linking within the matrix, with an emission spectrum that includes wavelengths that are most efficient at cross-linking used. As an example, a UV radiation source including spectral lines of less than 250 nm is used. Blocks 204 and 206 may also include a thermal treatment of the substrate and be referred to as ultraviolet thermal processing (UVTP). Substrate temperatures may range from around room temperature to about 450° C., for example around 400° C.

The process of FIG. 2 serves to selectively remove regions of isolated, organic porogen co-existing within the silicon-organic matrix within a ULK thin film, while preserving the organic groups bonded to the backbone of the silicon matrix. A selective organic removal mechanism followed by a UV exposure results in two phenomenon: first, the physical properties of the post-UV exposure thin film are improved; namely a reduced dielectric constant, k, and an increased hardness and Young's modulus (H/E). Second, throughput may be improved over UV-only processes, with the total cure time to obtain a film with specific k and WE properties reduced.

As indicated above, a porogen removal plasma employed in methods according to FIG. 1 or 2 may include a weak oxidizer (such as CO₂) and a reducing agent (such as H₂). Such a plasma is advantageously used over plasma such as a He/H₂ plasma as described below. For example, porogen removal by a He/H₂ inductively-coupled downstream plasma was compared to porogen removal by a CO₂/H₂ inductively-coupled downstream plasma. The results are shown in Table 1, below.

TABLE 1
Porogen removal with He/H₂ plasma and CO₂/H₂ plasmas

| Parameter | He/H₂ | CO₂/H₂ |
|---|---|---|
| C—Hₓ removal | 48.2% | 50.7% |
| Si—CH₃ damage | 2.1% | 0.4% |
| Scaled exposure time | 5x | X |

The characteristic percent (%) change in the Si—CH₃ and C—Hₓ infrared absorption regions of a ULK thin film (post cure k about 2.3) as measured by Fourier Transform Infrared (FTIR) spectroscopy for the He/H₂ and CO₂/H₂ treatment processes are shown in Table 1. A linear baseline was removed from the regions: 950 cm-1 to 1200 cm-1, 1200 cm-1 to 1300 cm-1, and 2825 cm-1 to 3075 cm-1, to extract the data for the Si—O—Si, Si—CH₃, and C—Hₓ features respectively. The area was integrated over these regions and the ratio of Si-CH₃/Si—O—Si and C—Hₓ/Si—O—Si computed for both the as-received and post-treatment states on the same ULK thin film sample. The percent change was then computed using these two measurements. The CO₂/H₂ process demonstrates a reduction in damage, superior porogen removal (as quantified by the C—Hₓ removal) and 80% reduction in treatment time compared to the He/H₂ process. It should be noted that the reduction in damage occurs despite CO₂ being an oxidizer. Without being bound by a particular theory, it is believed that this is because CO₂ plasmas have a lower electron temperature than He or H₂ plasmas.

The CO₂/H₂ process also compares favorably to a CO₂ process without H₂ or other reducing agent. Such a process is aggressive and unstable. However, the amount of H₂ or other reducing agent used to obtain a stable process may be relatively small; for example, a volumetric gas flow CO₂:(H₂ and CO₂) ratio of about 0.6 may be used to remove porogen without significant damage. Accordingly in some embodiments, a weak oxidizer:reducing agent ratio of 1:1 may be employed. In some implementations, the weak oxidizer:reducing agent ratio is no more than 2:1 to reduce damage to the matrix.

Without being bound by a particular theory, it is believed that CO₂ alone behaves like a strong oxidizer, with generated O radicals removing organic groups from the backbone. It is further believed that the addition of a reducing agent mediates the reaction in such a manner that damage is reduced. For example, with the addition of H₂ to a remote plasma generator, hydrogen species (e.g., H₂) react with O radicals to form water. Accordingly, in some embodiments, it is the presence of both the weak oxidizer and the reducing agent that results in an efficient, low damage, high removal process.

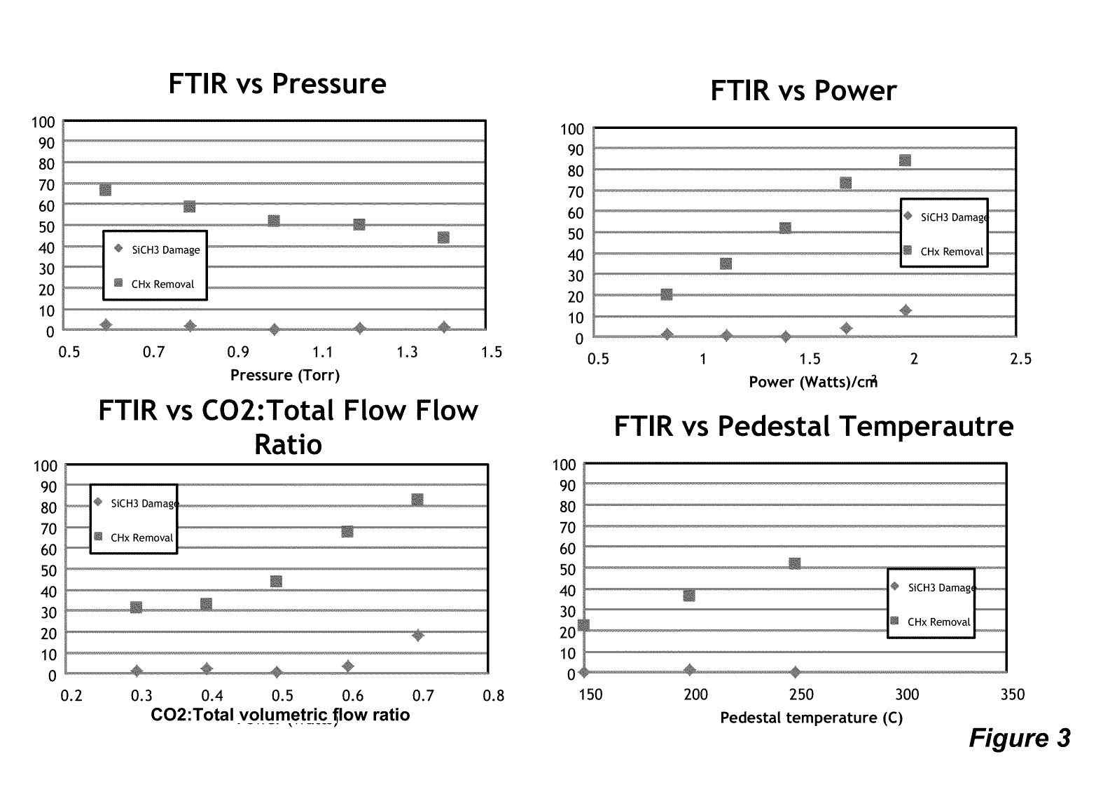

FIG. 3 shows plots of the percent change in Si—CH₃ and C—Hₓ infrared absorption regions of a ULK thin film (post-cure k about 2.3) using the CO₂/H₂ process as measured by FTIR spectroscopy as a function of: (a) process pressure, (b) RF power, (c) CO₂:total gas flow ratio, and (d) pedestal temperature. A linear baseline was removed from the regions: 950 cm-1 to 1200 cm-1, 1200 cm-1 to 1300 cm-1, and 2825 cm-1 to 3075 cm-1, to extract the data for the Si—O—Si, Si—CH₃, and C-Hx features respectively. The area was integrated over these regions and the ratio of Si-CH₃/Si—O—Si and C—Hₓ/Si—O—Si computed for both the as-received and post-treatment states on the same ULK thin film sample. The percent change was then computed using these two measurements.

Both CO₂ flow rate ratio (or other weak oxidizer concentration) and plasma generator power density (as measured in Watts/cm² substrate surface area) may be tuned to provide high porogen removal while minimizing damage. For example, referring to FIG. 3, a CO₂ flow rate ratio of 0.6 provides high porogen removal, with substantially no damage. At 0.7, the damage increases. In some implementations, a power density between about 1 and 1.8 Watts/cm² may be used. For example, also referring to FIG. 3, a power density of about 1.5 Watts/cm² may be used to provide high porogen removal with substantially no damage.

Table 2, below, shows results of various inductively-coupled downstream plasma treatments (compared to a no treatment control) and various post-treatment UV exposures. “B” bulb refers to a bulb having spectral lines less than 250 nm that efficiently cross-links. “AB” refers to sequential exposure to an “A” bulb that has an emission spectrum having wavelengths above 250 nm and exposure to a B bulb. The A bulb preferentially removes porogen. Duration of the treatment is given in units of

TABLE 2
Si—CH₃ cross-linking for various plasma and UV treatments

| | | | Si—CH₃ cross- |
|---|---|---|---|
| Treatment | | k | linking (%) |
| | Bulb B Time | | |
| | (min) | | |
| None | 4 | 2.35 | 16.64 |
| H2/He (5x) | 4 | 2.34 | 20.15 |
| H2/CO2 (x) | 4 | 2.33 | 22.18 |
| None | 6 | 2.44 | 19.17 |
| H2/He (5x) | 6 | 2.36 | 24.89 |
| H2/CO2 (x) | 6 | 2.31 | 27.40 |
| None | 8 | 2.48 | 23.03 |
| H2/He (5x) | 8 | 2.36 | 27.34 |
| H2/CO2 (x) | 8 | 2.31 | 28.43 |
| | Bulb AB Time | | |
| | (min) | | |
| None | 4 | 2.34 | 15.54 |
| H2/He (5x) | 4 | 2.31 | 17.84 |
| H2/CO2 (x) | 4 | 2.30 | 19.54 |
| None | 6 | 2.37 | 19.72 |
| H2/He (5x) | 6 | 2.24 | 20.07 |
| H2/CO2 (x) | 6 | 2.31 | 24.10 |
| None | 8 | 2.42 | 21.01 |
| H2/He (5x) | 8 | 2.34 | 21.98 |
| H2/CO2 (x) | 8 | 2.27 | 22.56 |

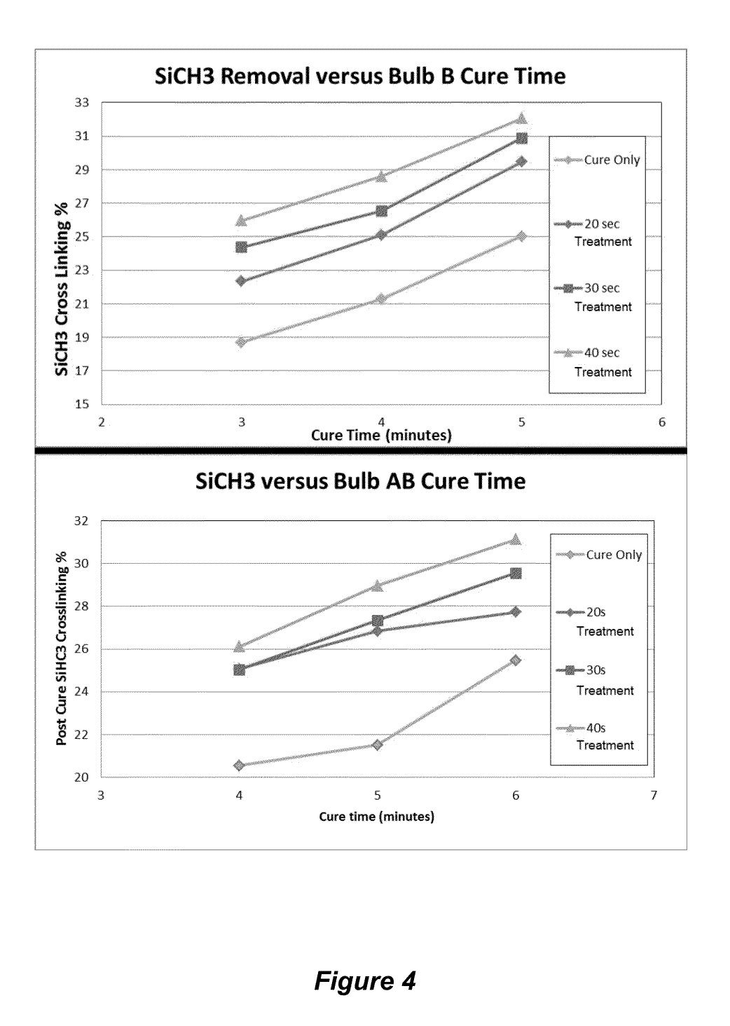

FIG. 4 shows SiCH₃ cross-linking versus Bulb B cure time and versus Bulb AB cure time.

FIG. 5a shows an example of a cross-sectional schematic diagram of a plasma apparatus with a processing chamber. The plasma apparatus 500 includes a processing chamber 550, which includes a substrate support 505 such as a pedestal, for supporting a substrate 510. The plasma apparatus 500 also includes a remote plasma source 540 over the substrate 510, and a showerhead 530 between the substrate 510 and the remote plasma source 540. Treatment species 520 can flow from the remote plasma source 540 towards the substrate 510 through the showerhead 530. A remote plasma may be generated in the remote plasma source 540 to produce treatment species 520. The remote plasma may also produce ions and other charged species of the treatment process gas. The remote plasma may further generate photons, such as UV radiation. Coils 544 may surround the walls of the remote plasma source 540 and generate a remote plasma in the remote plasma source 540.

In some embodiments, the coils 544 may be in electrical communication with a radio frequency (RF) power source or microwave power source. An example of a remote plasma source 540 with an RF power source can be found in the GAMMA®, manufactured by Lam Research Corporation of Fremont, Calif. Another example of an RF remote plasma source 540 can be found in the Astron®, manufactured by MKS Instruments of Wilmington, Mass., which can be operated at 440 kHz and can be provided as a subunit bolted onto a larger apparatus for processing one or more substrates in parallel. In some embodiments, a microwave plasma can be used with the remote plasma source 540, as found in the Astex®, also manufactured by MKS Instruments. A microwave plasma can be configured to operate at a frequency of 2.45 GHz.

In embodiments with an RF power source, the RF generator may be operated at any suitable power to form a plasma of a desired composition of radical species. Examples of suitable powers include, but are not limited to, powers between about 0.5 kW and about 6 kW. Likewise, the RF generator may provide RF power of a suitable frequency, such as 13.56 MHz for an inductively-coupled plasma. In some embodiments, the plasma power is kept below a level at which removal of organic species will occur, as discussed above with respect to FIG. 3.

A plasma treatment process gas can be delivered from a gas inlet 542 and into an internal volume of the remote plasma source 540. The power supplied to the coils 544 can generate a remote plasma with to form radicals of the treatment gas. The radicals formed in the remote plasma source 540 can be carried in the gas phase towards the substrate 510 through the showerhead 530. An example of a remote plasma source 655 with such a configuration can be described in U.S. Pat. No. 8,084,339 issued Dec. 27, 2011, which is incorporated herein by reference in its entirety and for all purposes.

In addition to radicals of the reducing gas species, the remote plasma can also generate and include ions and other charged species. In some embodiments, the remote plasma may include neutral molecules. Some of the neutral molecules may be recombined molecules of charged species. The showerhead 530 may act as a filter to remove high energy ions and photons.

In FIG. 5a, the plasma apparatus 500 may actively cool or otherwise control the temperature of the substrate 510. In some embodiments, it may be desirable to control the temperature of the substrate 510 to control the rate of the reaction and the uniformity of exposure to the remote plasma during processing. In some embodiments, the plasma apparatus 500 can include movable members 515, such as lift pins, that are capable of moving the substrate 510 away from or towards the substrate support 505. The movable members 515 may contact the lower surface of the substrate 510 or otherwise pick up the substrate 510 from the substrate support 505. In some embodiments, the movable members 515 may move the substrate 510 vertically and control the spacing between the substrate 510 and the substrate support 505. In some embodiments, the movable members 515 can include two or more actuatable lift pins.

In some embodiments, the plasma apparatus 500 can include a showerhead 530 that allows for control of the showerhead temperature. An example of a showerhead configuration that permits temperature control can be described in U.S. Pat. No. 8,137,467, issued Mar. 20, 2012, and U.S. Pat. No. 8,673,080, issued Mar. 18, 2014 both of which are incorporated herein by reference in their entireties and for all purposes. Another example of a showerhead configuration that permits temperature control can be described in U.S. Patent Publication No. 2011/0146571, published Jun. 23, 2011, which is incorporated herein by reference in its entirety and for all purposes. To permit active cooling of the showerhead 530, a heat exchange fluid may be used, such as deionized water or a thermal transfer liquid manufactured by the Dow Chemical Company in Midland, Mich. In some embodiments, the heat exchange fluid may flow through fluid channels (not shown) in the showerhead 530. In addition, the showerhead 530 may use a heat exchanger system (not shown), such as a fluid heater/chiller to control temperature. In some embodiments, the temperature of the showerhead 530 may be controlled to below about 30° C., such as between about 5° C. and about 20° C. The showerhead 530 may be cooled to reduce damage to the metal seed layer that may result from excess heat during processing of the substrate 510. The showerhead 530 may also be cooled to lower the temperature of the substrate 510, such as before and after processing the substrate 510.

In some embodiments, the temperature of the substrate support 505 may also be adjusted. In some embodiments, the substrate support 505 can be a pedestal with one or more fluid channels (not shown). The fluid channels may circulate a heat transfer fluid within the pedestal to actively cool or actively heat the pedestal, depending on the temperature of the heat transfer fluid. Embodiments that include such fluid channels and heat transfer fluids can be described in actively cooled pedestal systems discussed earlier herein. The circulation of the heat transfer fluid through one or more fluid channels can control the temperature of the substrate support 505. Temperature control of the substrate support 505 can control the temperature of the substrate 510 to a finer degree. In some embodiments, the temperature of the substrate support 505 can be adjusted to be between about room temperature and about 400° C.

In some embodiments, the plasma apparatus 500 may be part of or integrated with an UV treatment apparatus. Examples of UV treatment apparatus are described in U.S. Pat. No. 8,137,465, issued Mar. 20, 2102 and incorporated by reference herein for all purposes. The plasma apparatus may be implemented in a loadlock attached to a UV treatment apparatus, for example, or attached to a common transfer module as the UV treatment apparatus. A remote plasma apparatus implemented in a loadlock is disclosed in U.S. Pat. No. 8,217,513, issued Jun. 10, 2012 and incorporated by reference herein for all purposes.

Many different types of UV exposure apparatus may be employed. In some embodiments, the apparatus will include one or more chambers that house one or more substrates, with at least one chamber including a UV source. A single chamber may have one or more stations and may be employed for one, some or all operations. Each chamber may house one or more substrates for processing. For certain operations in which the substrate temperature is to be controlled, the apparatus may include a controlled temperature substrate support, which may be heated, cooled, or both. The support may also be controllable to provide defined substrate positions within a process module. The substrate support may rotate, vibrate, or otherwise agitate the substrate relative to the UV source.

FIG. 5b depicts the arrangement of a UV light source suitable for implementations of certain methods described herein. In the example of FIG. 5b, a cold mirror reflector diminishes the incidence of IR radiation on the substrate, while permitting UV radiation to be available for processing. For clarity, this figure depicts only one of the possible multiple processing stations available in an apparatus. Also, this figure omits depiction of the substrate for purposes of clarity, and shows a flood-type reflector. The principles depicted in FIG. 5b may also be applied to a focused reflector. Further, the UV apparatus may not include cold mirrors in certain embodiments.

Pedestal 573 is embedded into one station of a processing chamber 571. Window 575 is located appropriately above pedestal 573 to permit radiation of the substrate (not shown here) with UV output of the desired wavelengths from UV lamps 579 and 589. Suitable lamps for the UV light source may include, but are not limited to, mercury vapor or xenon lamps. Other suitable light sources include deuterium lamps, excimer lamps or lasers (e.g., excimer lasers and tunable variations of various lasers). Both lamps 579 and 589 are equipped with reflectors 577 and 587 which render their output into flood illumination. Reflectors 577 and 587 may themselves be made from “cold mirror” materials, i.e., they may also be designed to transmit IR and reflect UV radiation.

Radiation emanating directly from lamps 579 and 589 as well as that reflected from reflectors 577 and 587 is further incident upon a set of reflectors 581. These reflectors are also cold mirrors designed to reflect only those UV wavelengths that are desired as described above. All other radiation including visible and most particularly the IR is transmitted by this set of cold mirrors. Therefore the substrate may be radiated only by those wavelengths that cause the desired effect on the film. The specific angle, distance, and orientation of the cold mirror reflectors 581 with respect to the lamps 579 and 589 may be optimized to maximize the UV intensity incident on the substrate and to optimize the uniformity of its illumination.

The chamber 571 is capable of holding a vacuum and/or containing gases at pressures above atmospheric pressure. For simplicity, only one station of one chamber 571 is shown. It is noted that in some embodiments, chamber 571 is one chamber in a multi-chambered apparatus, although chamber 571 could alternatively be part of a stand-alone single chambered apparatus. In either case, the chamber(s) may have one or more than one station. In some embodiments of the present invention, the UV process modules have one station. Suitable apparatus for implementation of the invention may include configurations as described herein of NOVA, Sequel, Vector and SOLA systems from Lam Research, Inc. of Fremont, Calif., and Endura, Centura, Producer and Nanocure systems from Applied Materials of Santa Clara, Calif. In some implementations, the UV cure chamber may be equipped with a remote plasma source as in FIG. 5a, such that both remote plasma and UV processing operations may be performed in one chamber.

Note that the UV light source configuration of FIG. 5b is only an example of a suitable configuration. In general, the lamp(s) are arranged to provide uniform UV radiation to the substrate. For example, other suitable lamp arrangements can include arrays of circular lamps concentrically or otherwise arranged, or lamps of smaller length arranged at 90 degree and 180 degree angles with respect to each other may be used. The light source(s) can be fixed or movable so as to provide light in appropriate locations on the substrate. Alternatively, an optical system, including for example a series of movable lenses, filters, and/or mirrors, can be controlled to direct light from different sources to the substrate at different times.

The UV light intensity can be directly controlled by the type of light source and by the power applied to the light source or array of light sources. Factors influencing the intensity of applied power include, for example, the number or light sources (e.g., in an array of light sources) and the light source types (e.g., lamp type or laser type). Other methods of controlling the UV light intensity on the substrate sample include using filters that can block portions of light from reaching the substrate sample. As with the direction of light, the intensity of light at the substrate can be modulated using various optical components such as mirrors, lenses, diffusers and filters. The spectral distribution of individual sources can be controlled by the choice of sources (e.g., mercury vapor lamp vs. xenon lamp vs. deuterium lamp vs. excimer laser, etc.) as well as the use of filters that tailor the spectral distribution. In addition, the spectral distributions of some lamps can be tuned by doping the gas mixture in the lamp with particular dopants such as iron, gallium, etc.

In certain embodiments, a system controller, such as system controller 535, is employed to control aspects of the process described herein. The system controller will typically include one or more memory devices and one or more processors. The processor may include a CPU or computer, analog and/or digital input/output connections, stepper motor controller boards, etc. Typically there will be a user interface associated with system controller. The user interface may include a display screen, graphical software displays of the apparatus and/or process conditions, and user input devices such as pointing devices, keyboards, touch screens, microphones, etc.

In certain embodiments, the system controller may also control all of the activities during the process, including gas flow rate, chamber pressure, plasma generator, substrate transfer, and UV radiation parameters. The system controller executes system control software including sets of instructions for controlling the timing, mixture of gases, chamber pressure, pedestal (and substrate) temperature, plasma power, and other parameters of a particular process. The system controller may also control concentration of various process gases in the chamber by regulating valves, liquid delivery controllers and MFCs in the delivery system as well as flow restriction valves and the exhaust line. The system controller executes system control software including sets of instructions for controlling the timing, flow rates of gases and liquids, chamber pressure, substrate temperature, plasma power and other parameters of a particular process. Other computer programs stored on memory devices associated with the controller may be employed in some embodiments. In certain embodiments, the system controller controls the transfer of a substrate into and out of various components of the apparatuses.

The computer program code for controlling the processes in a process sequence can be written in any conventional computer readable programming language: for example, assembly language, C, C++, Pascal, Fortran or others. Compiled object code or script is executed by the processor to perform the tasks identified in the program. The system software may be designed or configured in many different ways. For example, various chamber component subroutines or control objects may be written to control operation of the chamber components necessary to carry out the described processes. Examples of programs or sections of programs for this purpose include process gas control code and pressure control code.

The controller parameters relate to process conditions such as, for example, timing of each operation, pressure inside the chamber, substrate temperature, and process gas flow rates. These parameters are provided to the user in the form of a recipe, and may be entered utilizing the user interface. Signals for monitoring the process may be provided by analog and/or digital input connections of the system controller. The signals for controlling the process are output on the analog and digital output connections of the apparatus.

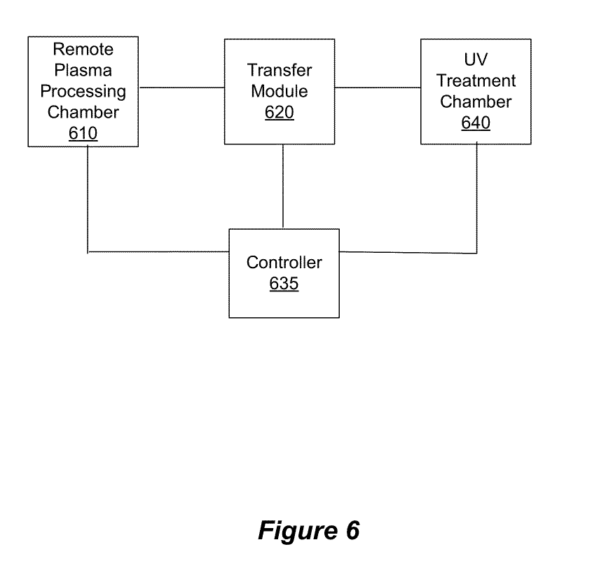

In some implementations, a remote plasma processing chamber may be connected to a UV processing chamber by a transfer module. An example of such an arrangement is illustrated in FIG. 6, in which remote plasma processing chamber 610 is connected to UV treatment chamber 640 by a transfer module 620. A controller 635 may control aspects of remote plasma processing, UV radiation exposure and transfer between chambers 610 and 640.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The disclosed methods and apparatuses may also be implemented in systems including lithography and/or patterning hardware for semiconductor fabrication. Further, the disclosed methods may be implemented in a process with lithography and/or patterning processes preceding or following the disclosed methods. The apparatus/process described hereinabove may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically comprises some or all of the following steps, each step enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

Although the foregoing has been described in some detail for purposes of clarity of understanding, it will be apparent that certain changes and modifications may be practiced within the scope of the appended claims. It should be noted that there are many alternative ways of implementing the processes, systems and apparatus disclosed herein. Accordingly, the present embodiments are to be considered as illustrative and not restrictive, and the invention is not to be limited to the details given herein.

What is claimed is:

1. A method comprising:
providing a precursor film including a dielectric matrix and a porogen;
exposing the precursor film to a downstream plasma generated from a process gas including a reducing agent and a weak oxidizer to thereby remove porogen and form a porous dielectric film.

2. The method of claim 1, further comprising exposing the porous dielectric film to UV radiation to thereby increase cross-linking.

3. The method of claim 2, wherein exposing the porous dielectric film to UV radiation comprises exposing the porous dielectric film to a first emission spectrum and then exposing the porous dielectric film to a second emission spectrum, wherein the first and second emission spectra are different.

4. The method of claim 1, wherein the plasma is generated by an inductively-coupled plasma generator.

5. The method of claim 1, wherein the weak oxidizer is selected from carbon dioxide, water, methanol, ethanol, isopropyl alcohol, and combinations thereof.

6. The method of claim 1, wherein the reducing agent is selected from molecular hydrogen, ammonia, acetic acid, formic acid, and combinations thereof.

7. The method of claim 1, wherein a weak oxidizer:reducing agent volumetric flow ratio is 1:1 or greater.

8. The method of claim 1, wherein a weak oxidizer:reducing agent volumetric flow ratio is between 1:1 and 2:1.

9. The method of claim 1, wherein the reducing agent is molecular hydrogen (H₂) and the weak oxidizer is carbon dioxide (CO₂).

10. The method of claim 1, wherein radical species are predominant in the downstream plasma.

11. The method of claim 1, wherein a power used to generate the downstream plasma is between about 1.0 and 1.8 Watts per cm² of surface area of a substrate on which the precursor film is disposed.

12. An apparatus comprising:
a processing chamber;
a substrate support for holding a substrate in the processing chamber;
a remote plasma source over the substrate support;
a showerhead between the remote plasma source and the substrate support; and
a controller with instructions to perform the following operations:
(a) receiving a substrate including a precursor film including a dielectric matrix and a porogen;
(b) inletting reducing agent and a weak oxidizer gases into the remote plasma source;
(c) applying a power to the remote plasma generator to generate plasma species from the reducing agent and a weak oxidizer gases;
(d) directing remote plasma species including weak oxidizer and reducing agent species through the showerhead; and
(e) exposing a substrate to the remote plasma species in (c).

13. The apparatus of claim 12, wherein the controller comprises instructions to inlet the reducing agent and a weak oxidizer gases into the remote plasma generator at a weak oxidizer:reducing agent volumetric flow ratio between 1:1 and 2:1.

14. The apparatus of claim 12, wherein the controller comprises instructions to apply a power between 1 and 1.8 Watts per cm² of surface area of the substrate.

15. The apparatus of claim 12, further comprising a UV cure chamber.

16. The apparatus of claim 12, wherein the controller comprises instructions to, after (e), expose the substrate to UV radiation.

17. The apparatus of claim 16, wherein the controller comprises instructions to expose the porous dielectric film to a first emission spectrum and then expose the porous dielectric film to a second emission spectrum, wherein the first and second emission spectra are different.
